(19) United States
(12) Patent Application Publication
(10) Pub. No.: US 2006/0270190 A1
(43) Pub. Date: Nov. 30, 2006

(54) Method of transferring a thin crystalline semiconductor layer

(75) Inventors: Michael A. Nastasi, Santa Fe, NM (US); Lin Shao, Los Alamos, NM (US); Phillip E. Thompson, Springfield, VA (US); Silvanus S. Lau, San Diego, CA (US); N. David Theodore, Mesa, AZ (US); Terry L. Alford, Phoenix, AZ (US); James W. Mayer, Phoenix, AZ (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: The Regents of the University of California

(21) Appl. No.: 11/137,979

(22) Filed: May 25, 2005

(51) Int. Cl. H01L 21/30

(52) U.S. Cl. 438/458

(57) ABSTRACT

A method for transferring a monocrystalline, thin layer from a first substrate onto a second substrate involves deposition of a doped semiconductor layer on a substrate and epitaxial growth of a thin, monocrystalline, semiconductor layer on the doped layer. After bonding the thin epitaxial monocrystalline semiconductor layer to a second substrate, hydrogen is introduced into the doped layer, and the thin layer is cleaved and transferred to the second substrate, with the cleaving controlled to happen at the doped layer.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates generally to silicon-on-insulator (SOI) wafers and more particularly to a method for transferring an ultrathin layer of monocrystalline semiconductor from one substrate to another.

### BACKGROUND OF THE INVENTION

Past methods for producing silicon-on-insulator (SOI) wafers have involved epitaxial growth of silicon on an insulating substrate, or implantation of oxygen directly into silicon to form buried silicon dioxide layers (SIMOX™). In recent years, other methods have involved the transfer of a thin layer of semiconductor. One example of such a transfer method can be found in U.S. Pat. No. 4,846,931 to T. J. Gmitter et al. entitled “Method for Lifting-off Epitaxial Films”. According to the '931 patent, an epitaxial film is grown on a single crystal substrate. Afterward, a thin release layer positioned in between the epitaxial film and the substrate is selectively etched away. As the release layer is removed, the edges of the epitaxial film curl upward and away from the substrate and the epitaxial layer is peeled away. This approach is presently unsuitable for the preparation of SOI wafers because it is limited for lift-off of a film having a small area (about 1 cm²), while films having an area of 100 to 1000 cm² are presently required for the fabrication of SOI wafers.

A method for transferring monocrystalline layers over thermally oxidized silicon handle wafers by bonding and single etch back of porous silicon is described by T. Yonehara et al. in “Epitaxial Layer Transfer by Bond and Etch Back of Porous Si”, Appl. Phys. Lett. 64, (1994) pp. 2108-2110. According to this paper, a thick substrate is made thinner by etching away the substrate until an etch stop (a porous silicon layer) is reached. The method has the disadvantage of the high cost to etch an entire semiconductor wafer.

Another method for transferring a semiconductor layer is described in U.S. Pat. No. 5,374,564 to M. Bruel, entitled “Process for the Production of Thin Semiconductor Material Films”. According to the '564 patent, hydrogen ions are implanted into a semiconductor substrate, and then are transformed into a quasi-continuous hydrogen layer. This method has disadvantages of the requirement of a high fluence of hydrogen (above 5×10¹⁶ cm⁻²), the difficulty in transferring an ultra thin (<0.1 micron) layer, and the low crystalline quality of the transferred layer due to surface damage induced by the hydrogen ion implantation.

Attempts were made to improve the Bruel method. In U.S. Pat. No. 5,877,070 to U. M. Goesele et al. entitled “Method for the Transfer of Thin Layers of Monocrystalline Material to a Desirable Substrate,” for example, a hydrogen-trap-inducing element such as boron or phosphorus is implanted into a substrate to create a disordered layer that divides the substrate into a lower portion (most of the substrate) and an upper portion that is transferred to a different substrate. After the creation of the disordered layer, hydrogen is implanted near the disordered layer and the substrate is then subjected to heat treatment. The upper portion of the substrate is then bonded to another substrate and the disordered layer is split, thereby transferring the upper portion (i.e. the thin layer) from the first substrate to the second substrate. While this method allows a somewhat reduced dosage requirement for the hydrogen implantation, it is still affected by the same problems as described above for the Bruel method.

U.S. Pat. No. 6,352,909 to A. Y. Usenko entitled “Process for Lift-Off of a Layer From a Substrate” is concerned with another attempt at improving the Bruel method. The '909 patent describes forming a buried layer of defects by implantation. The buried defect layer is used to trap hydrogen. A disadvantage of this method is that the surface of the layer to be transferred is heavily damaged during the implantation and the damage is difficult to fix, even by annealing at a relatively high-temperature.

In U.S. Pat. No. 6,806,171 to A. Ulyashin et al. entitled “Method of Producing a Thin Layer of Crystalline Material,” a porous silicon layer is created on a silicon substrate, and a nonporous epitaxial layer is grown on the porous layer. The porosity of the now-buried porous layer is increased by hydrogenation techniques, and then the epitaxial layer is cleaved from the sandwich structure at the porous layer. After cleavage, the transferred layer needs to be smoothened. Similar to all of the prior art methods mentioned above, this method does not provide any improvement on the smoothness of the transferred layer.

U.S. patent application 20050070071 to F. Henley et al. entitled “Method and Device for Controlled Cleaving Process” discloses a controlled cleaving process that involves introducing H atoms directly into a stressed region by hydrogen ion implantation. Damage cascades created within the stressed region degrade the crystalline quality and increase the roughness of the transferred layer.

Two approaches that are described by Cheng et al. in U.S. Pat. No. 6,573,126 and in U.S. Pat. No. 6,713,326, both entitled “Process for Producing Semiconductor Article Using Graded Epitaxial Growth”, involve using hydrogen ion implantation for lift-off of a semiconductor layer from a heterostructure that includes both a graded SiGe layer and a strain-relaxed SiGe layer. After thermal annealing, a zigzag network of microcracks results in a rough surface of the transferred layer. These approaches have the same limitations as those described by Bruel et al. in U.S. Pat. No. 5,374,564. In particular, a fluctuation in thickness as high as several tens of percent occurs when forming a layer of submicron thickness, and the formation of a uniform layer becomes a large problem for transferring a layer of material having a thickness of less than about 100 nanometers (1 nm=10⁻⁹ m). The difficulty of forming a thin film with high crystalline quality becomes more severe with an increase in wafer diameter.

There remains a need for a better method for transferring ultrathin layers of crystalline semiconductor material.

Accordingly, an object of the present invention is to provide a method for transferring an ultrathin layer of semiconductor material.

Additional objects, advantages and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

In accordance with the purposes of the present invention, as embodied and broadly described herein, the present invention includes a method for transferring a thin layer of crystalline semiconductor material. According to the method, a first heterostructure is formed by depositing a doped semiconductor layer on a first substrate. The doped semiconductor layer includes at least one dopant selected from boron, gallium, indium, phosphorus, arsenic, and antimony. After depositing the doped semiconductor layer, a monocrystalline epitaxial semiconductor layer is deposited on the doped layer. Afterward, hydrogen atoms are introduced into the first heterostructure and allowed to diffuse into the doped layer. Afterward, the monocrystalline epitaxial semiconducting layer of the first heterostructure is bonded to a second substrate to form a second heterostructure, and the second heterostructure is split at the doped semiconductor layer, thereby transferring the monocrystalline epitaxial semiconductor layer to the second substrate. The invention also includes a method for forming a semiconductor structure that involves forming a first heterostructure by depositing a doped semiconductor layer on a first substrate and thereafter depositing a semiconductor layer on the doped layer; introducing hydrogen atoms into the doped layer; bonding the first heterostructure to a second substrate to form a second heterostructure; and splitting said second heterostructure at the doped layer.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1a-c show schematic representations that illustrate the method of the invention. FIG. 1a shows the introduction of hydrogen into a first heterostructure having a layer of doped semiconductor in between a thin epitaxial semiconductor layer and a much thicker substrate layer; FIG. 1b shows the bonding of the epitaxial layer of the heterostructure to a second substrate; and FIG. 1c shows the transferring of the epitaxial layer to the second substrate.

FIG. 2 shows a schematic representation of the introduction of hydrogen into the heterostructure by ion implantation.

FIG. 3 shows a schematic representation of the introduction of hydrogen into the heterostructure by an electrolytic process.

FIG. 4 shows an example hydrogen depth profile from hydrogenated silicon that has a boron-doped silicon layer, of about 3 nanometers in thickness, at a depth of 200 nanometers beneath the surface. Hydrogen (H) atom distributions within virgin Si (i.e. without the boron-doped layer) before and after hydrogenation are also plotted for comparison; and

FIG. 5 shows TEM micrographs from (a) hydrogenated virgin Si (i.e. without the boron-doped layer) and (b) hydrogenated Si that has a boron-doped silicon layer, of about 3 nanometers in thickness, at a depth of 200 nanometers beneath the surface.

### DETAILED DESCRIPTION

Briefly, the present invention is concerned with transferring a thin layer of crystalline semiconductor from a first substrate to a second substrate. A thin layer of doped semiconductor is deposited on the surface of a semiconductor substrate, and then a thin epitaxial layer of monocrystalline semiconductor is deposited on top of the doped layer. Hydrogen (and/or deuterium) atoms are introduced into this heterostructure and allowed to diffuse into the doped layer. Afterward, the thin epitaxial monocrystalline semiconductor layer is bonded to another substrate. A direct wafer bonding or anodic bonding approach, or some other approach may be used to form an intimate and strong bond between the epitaxial layer and the second substrate. After bonding the epitaxial layer to the second substrate, the epitaxial layer is separated from the first substrate by splitting at the doped layer. The splitting results in transfer of the thin epitaxial monocrystalline semiconductor layer to the second substrate.

The splitting at the doped layer may be controlled so that it occurs when hydrogen is introduced into the heterostructure.

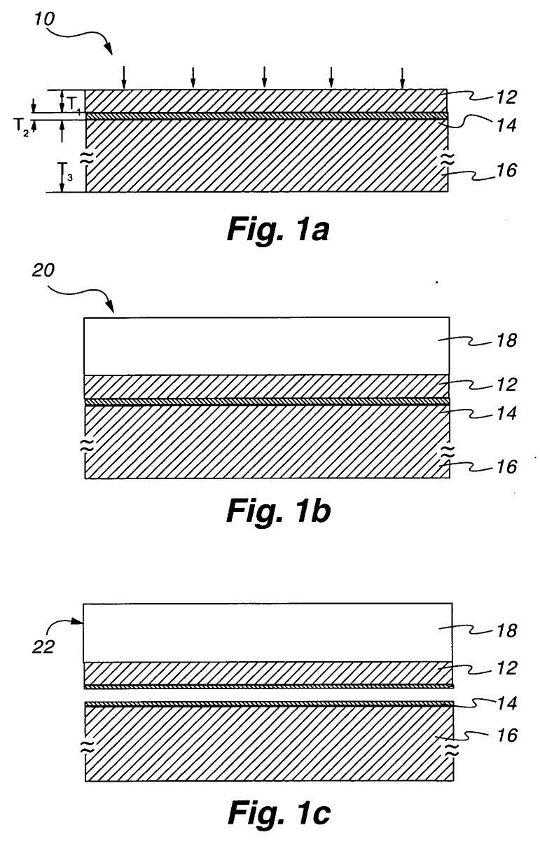

Reference will now be made in detail to the present preferred embodiments of the invention. Similar or identical structure is identified using identical callouts. A schematic representation of the method of the present invention is illustrated in FIGS. 1a, 1b, and 1c.

FIG. 1a shows heterostructure 10, which includes thin epitaxial monocrystalline layer 12, thick substrate layer 16, and doped semiconductor layer 14 in between layer 12 and layer 16.

In some embodiments, monocrystalline layer 12 includes one or more group IV elements such as carbon, silicon, and germanium. Preferably, layer 12 is a layer of epitaxial monocrystalline semiconductor of the formula Si₁₋ₓCₓ with C content in the range of from about 1 percent to about 100 percent, or a layer of Si₁₋ₓGeₓ with Ge content in a range of about 0 percent to about 100 percent. Most preferably, layer 12 is a layer of epitaxial monocrystalline silicon.

Layer 14 is an epitaxial layer and includes a group IV semiconductor of one or more elements selected from silicon, carbon, and germanium. Semiconductor layer 14 is doped with one or more dopants selected from boron, gallium, indium, phosphorus, arsenic, and antimony.

Substrate layer 16 is a semiconductor layer. In an embodiment, layer 16 is monocrystalline silicon. In another embodiment, layer 16 has a multilayer structure. In some embodiments, layer 16 includes one or more group IV elements. The layer 16 may include, for example, Si, S_{1-y}C_{y}, Si_{1-x-y}CₓGe_{y}, or S_{1-y}Ge_{y}, with Ge or C content in a range of from about 1 percent to about 100 percent.

Layer 12 has a thickness T₁ of from about 10 Angstrom to about 100,000 Angstrom. In certain embodiments, T₁ is less than 2000 Angstrom. Layer 14 has a thickness T₂ of from about 2 Angstrom to about 10,000 Angstrom. Preferably, when boron is a dopant, layer 14 has a thickness T₂ of less than about 1000 Angstrom. In certain embodiments, T₂ is less than 100 Angstrom in thickness. Layer 16 has a thickness T₃ of from about 1 μm to about 1000 μm (1 μm=10⁻⁶ meters). In certain embodiments, T₃ is less than about 600 μm.

The growth of layers 12, 14, and 16 to form heterostructure 10 may be accomplished by any known method for depositing layers of semiconductor materials. These methods include, but are not limited to, thermal chemical vapor deposition, reduced-pressure chemical vapor deposition, molecular beam epitaxy, low temperature molecular beam epitaxy, and sputtering. In some preferred embodiments, layer 12 and layer 14 are grown by one of the methods mentioned above and layer 16 (or part of layer 16) is grown by techniques known in the art as “Czochralski Crystal Growth” or “Float Zone Crystal Growth”. Usually, layer 16 has a high degree of chemical purity, a high degree of crystalline perfection, and high structure uniformity.

In an embodiment, the growth of layer 12 and layer 14 is realized by chemical vapor deposition. Silane (SiH₄) source gas, for example, may be used to deposit a monocrystalline silicon layer 12. Usually, a high growth rate is readily achieved by deposition at high chemical vapor deposition temperatures. The high temperatures may also reduce the incorporation of impurities and improve layer uniformity. Adequate growth rates, i.e., >0.01 Angstrom/s using SiH₄ may be attained at a temperature of about 550 degrees Celsius.

An appropriate surface-cleaning step may be performed if any of layers 12, 14, or 16 has been exposed to the air. The cleaning may involve chemical etching such as dipping into diluted hydrofluoric acid or heating at an elevated temperature under vacuum.

Hydrogenation of heterostructure 10 is achieved by forming ionized hydrogen plasma about heterostructure 10 within an enclosing chamber and by applying repetitive high voltage negative pulses to heterostructure 10 to drive the hydrogen ions into exposed surfaces of heterostructure 10. It should be understood that hydrogenation may involve using normal hydrogen (H₂), deuterium (D₂), hydrogen deuterium (HD), or mixtures thereof. Hydrogenation is performed with heterostructure 10 at an elevated temperature for a duration long enough to introduce enough hydrogen into heterostructure 10 and diffuse the hydrogen into doped layer 14 where at least some of it is trapped. Sub-surface microcracks may be formed during this stage, but the temperature of the heterostructure should be controlled below the temperature at which significant blistering of the surface of the heterostructure occurs. The energy of the hydrogen used for hydrogenation is in the range of about 50 eV to about 50 keV. In some embodiments, the energy of the hydrogen is below 1 keV, and the hydrogenation temperature is below about 600 degrees Celsius, and the hydrogenation duration is less than 10 hours. In an embodiment, the energy of the hydrogen is 500 eV and the substrate temperature is about 300 degrees Celsius and hydrogenation duration is less than about 3 hours.

FIG. 1b shows a schematic representation of the heterostructure 20 produced after bonding the monocrystalline epitaxial semiconductor layer 12 to second substrate 18. Second substrate 18 is preferably a material selected from silicon, germanium, oxidized silicon, glass, fused quartz, sapphire, gallium nitride, and silicon carbide. An intimate and strong bond between layer 12 and substrate 18 may be realized using, for example, direct wafer bonding or anodic bonding.

FIG. 1c shows a schematic representation of the transfer of ultrathin monocrystalline epitaxial semiconductor layer 12 onto second substrate 18 to form structure 22. This stage may involve the heat treatment of heterostructure 20 (FIG. 1b), which results in separation of ultrathin epitaxial monocrystalline semiconductor layer 12 from doped layer 14. This stage may also involve applying an external force to heterostructure 10 at the doped layer. External forces include, but are not limited to, bending heterostructure 10, or using a solid razor blade or a gas blade to cleave heterostructure at doped layer 14. In any case, the separation is controlled to happen within doped layer 14.

The heat treatment in the stage of layer transfer is usually at a temperate above about 500 degrees Celsius. It is expected that the threshold temperature for layer transfer may be lower than temperatures usually required by other methods, which would greatly benefit the layer transfer if substrate 18 has a thermal expansion coefficient that is very different from that of the transferred layer (i.e. layer 12).

After the layer transfer, part of doped layer 14 may still be attached to layer 12. Therefore, an additional step of etching or surface cleaning may be needed to remove the residual materials from the layer 12.

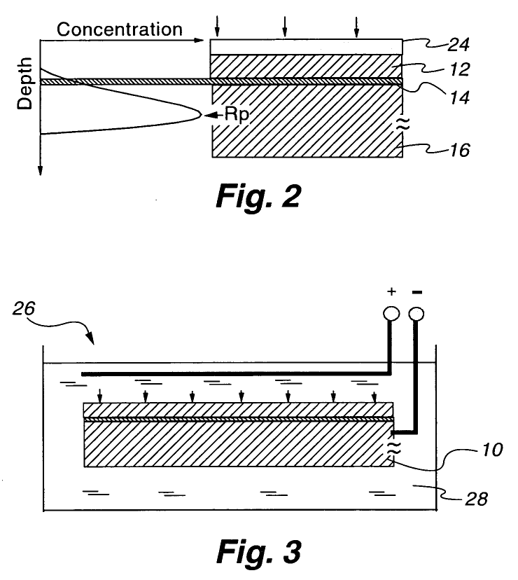

Hydrogenation by hydrogen plasma is a presently preferred embodiment. Various methods to introduce hydrogen can be used alternatively. In an embodiment exemplified by FIG. 2, hydrogen ion implantation is used to introduce hydrogen into heterostructure 10. The distribution of the implanted hydrogen in heterostructure 10 usually has a Gaussian-like shape with its concentration peaked at a location denoted in FIG. 2 by Rp (the projected range). The Rp may be controlled by varying the hydrogen ion implantation energy. Typically, the implantation energy is in a range from about 1 keV to about 200 keV. The Rp may be controlled to be either shallower or deeper than the location of doped layer 14. The implanted hydrogen should be able to migrate and to be trapped within doped layer 14. The hydrogen migration and trapping may occur during ion impanation or during thermal annealing after implantation.

In an embodiment of the invention, heterostructure 10 may optionally include encapsulating layer 24 (shown in FIG. 2) on monocrystalline semiconductor layer 12 to reduce the penetration of ions into heterostructure 10, thereby controlling the depth of the implanted hydrogen. Encapsulating layer 24 also offers a protective function by minimizing contamination of the heterostructure from possible contamination. In an embodiment, encapsulating layer 24 is silicon oxide with a thickness of from about 10 nm to about 1000 nm. Encapsulating layer 24 may be removed after the implantation by, for example, gas phase etching or by dipping heterostructure 10 into a dilute solution of acid (HF, for example).

The temperature of the first substrate during ion implantation should be controlled to be low enough to avoid the quick diffusion and escape of implanted hydrogen from the surface. Usually, the implantation temperature should be below about 500 degrees Celsius. Preferably, the temperature is from about 100 degrees Celsius to about 500 degrees Celsius.

In a still further particular embodiment, the introduction of hydrogen into heterostructure 10 may be realized electrolytically. FIG. 3 is a schematic representation of an electrolytic set-up 26 for introducing hydrogen into heterostructure 10. As FIG. 3 shows, heterostructure 10 is in electrolytic contact with electrolyte 28. When electrolyte 28 decomposes during the electrolysis, monatomic hydrogen is produced. A suitable electrolyte should be chosen in order to avoid significant damage to the surface of heterostructure 10 by oxidation or etching. Suitable electrolytes include, but are not limited to, acids such as H₃PO₄, HF, HCl, H₂SO₄, and H₃COOH. After the electrolysis, an appropriate surface cleaning may be performed to remove the hydrogen-rich surface.

The following EXAMPLE is given to illustrate an embodiment of the present invention. The EXAMPLE is given for illustrative purposes only, and the invention should not be limited to this embodiment. The embodiment that will now be described in conjunction with the above drawings relates to the lift-off process to transfer a thin film in a monocrystalline silicon wafer with the aid of plasma hydrogenation. The disclosed process permits fabrication of an ultra thin top silicon layer in the final silicon-on insulator wafer with its thickness being controllable.

### EXAMPLE

On top of a substrate of (100) 500 ohm-cm silicon, an epitaxial boron-doped silicon layer was deposited by molecular beam epitaxy growth (MBE). The thickness of the boron-doped layer was about 3 nm, and the boron concentration was around 1×10²¹ cm⁻³. On top of this boron-doped layer, a 200 nm thick crystalline Si layer was deposited. The resulting heterostructure was hydrogenated using hydrogen plasma, first at a temperature of about 250-300 degrees Celsius for about 1 hour, and then at a temperature of about 300-350 degrees Celsius for about two more hours. The bias voltage was 500 volts and the working pressure was 1.3 torr.

For the purpose of comparison, a virgin silicon wafer without a doped layer was also hydrogenated using the conditions mentioned above.

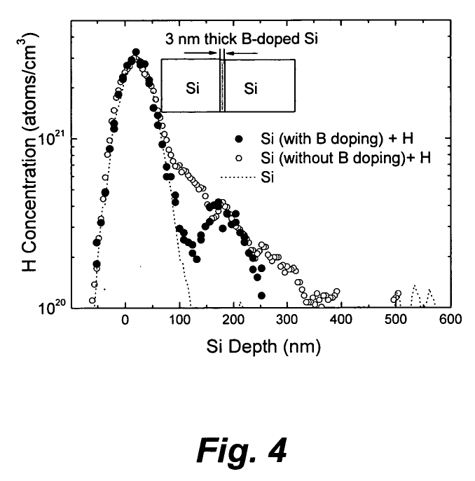

FIG. 4 shows a graph of hydrogen concentration as a function of depth in silicon, measured using elastic recoil detection analysis. The filled circle symbols relate to hydrogen in the heterostructure having a boron-doped layer. The empty circle symbols relate to hydrogen in the silicon wafer without the doped layer. A hydrogen-trapping peak was observed at the depth of the boron-doped layer. The dashed line relates to hydrogen contamination present at the surface of a silicon wafer prior to hydrogenation.

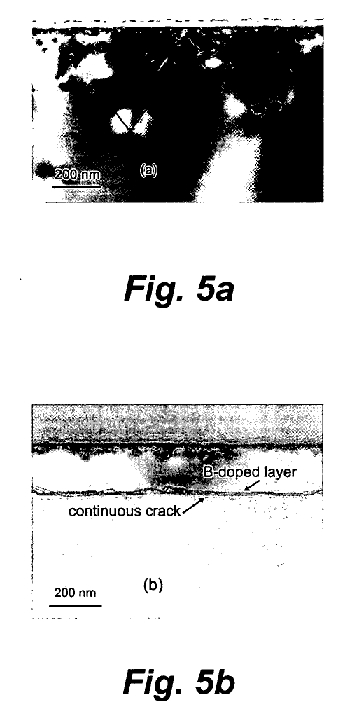

FIG. 5a shows a transmission electron microscopy (TEM) image of a cross section of virgin Si after hydrogenation. A dense band of platelets, with (111) crystal orientations formed over a depth range of 0 to 300 nm. A few platelets formed at even greater depths. As FIG. 5a shows, no cracking of the virgin Si was observed after hydrogenation.

FIG. 5b shows a TEM image of a cross-section of a Si heterostructure having a 3-nm thick boron-doped silicon layer after plasma hydrogenation. At the depth of the B-doped layer 14, a continuous (100) crack has formed. Importantly, cleavage was constrained at the boron-doped layer. FIG. 5b also shows that irradiation-induced damage and platelet formation are significantly suppressed in the epitaxial Si layer as compared with FIG. 5a, which shows significant irradiation-induced damage. These results indicate that the method of the present invention provides the following advantages: 1) the ability to control cleavage at the boron-doped layer; 2) the ability to reduce the surface roughness of the transferred layer as a result of smoother cleavage; and 3) the ability to improve the crystalline quality of the transferred layer.

In summary, the present invention relates to transferring a thin monocrystalline semiconductor layer from one substrate to another. The present invention may result in significant improvements that have not been achieved by earlier methods, such as in the quality, surface smoothness, and control of the thickness of the transferred layer.

The foregoing description of the invention has been presented for purposes of illustration and description and is not intended to be exhaustive or to limit the invention to the precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated. Although the invention has been disclosed with reference to its preferred embodiments, from reading this description those of skill in the art can appreciate changes and modifications that may be made which do not depart from the scope and spirit of the invention as described above and claimed hereafter. It is intended that the scope of the invention be defined by the claims appended hereto.

What is claimed is:

1. A method for transferring a thin semiconductor layer comprising:
forming a first heterostructure by depositing a layer of doped semiconductor on a first substrate and thereafter depositing a monocrystalline epitaxial semiconductor layer on the doped layer, wherein the layer of doped semiconductor comprises at least one dopant selected from the group consisting of boron, gallium, indium, phosphorus, arsenic, and antimony,;
introducing hydrogen atoms into the first heterostructure and allowing the hydrogen atoms to diffuse into the layer of doped semiconductor;
bonding the layer of doped semiconductor to a second substrate to form a second heterostructure; and
splitting the second heterostructure at the layer of doped semiconductor, thereby transferring the monocrystalline epitaxial semiconductor layer to the second substrate.

2. The method of claim 1, wherein the epitaxial monocrystalline layer comprises at least one element selected from the group consisting of silicon, carbon, and germanium.

3. The method of claim 1, wherein the doped semiconductor comprises at least one element selected from the group consisting of silicon, carbon, and germanium.

4. The method of claim 1, wherein the epitaxial monocrystalline semiconductor is silicon, the doped semiconductor comprises silicon, and the first substrate is silicon.

5. The method of claim 1, wherein splitting the second heterostructure comprises subjecting said second heterostructure to a transfer heat-treatment to produce cracks within the doped semiconductor layer.

6. The method of claim 1, further comprising heating the first heterostructure to a temperature of from about 100 degrees Celsius to about 1000 Celsius for at least 1 second as hydrogen diffuses into the doped layer.

7. The method of claim 1, wherein the introduction of hydrogen into the first heterostructure comprises plasma hydrogenation.

8. The method of claim 7, wherein plasma hydrogenation comprises radiofrequency plasma hydrogenation or DC plasma hydrogenation.

9. The method of claim 7, wherein plasma hydrogenation comprises an energy of ionized hydrogen of from about 50 eV to about 100 keV.

10. The method of claim 7, wherein plasma hydrogenation comprises an energy of ionized hydrogen of less than about 1 keV.

11. The method of claim 7, wherein the temperature of the first heterostructure during plasma hydrogenation is low enough to minimize blistering on the surface of the first heterostructure.

12. The method of claim 7, wherein the temperature of the first heterostructure during plasma hydrogenation is at least 100 degrees Celsius.

13. The method of claim 1, wherein the introduction of hydrogen into the first substrate comprises implantation, wherein hydrogen comprises normal hydrogen, deuterium, and mixtures thereof.

14. The method of claim 1, further comprising forming an encapsulating layer of silicon dioxide on the first heterostructure before introducing hydrogen atoms into the first heterostructure.

15. The method of claim 14, wherein the temperature of the first heterostructure during hydrogen implantation is from about minus 196 degrees Celsius to about 500 degrees Celsius.

16. The method of claim 1 wherein the introduction of hydrogen into the first heterostructure comprises electrically connecting the first heterostructure to an electrolytic cell and exposing the first heterostructure to an electrolyte in the electrolytic cell, wherein at least some of the electrolyte dissociates to produce hydrogen ions.

17. The method of claim 1, further comprising subjecting the first heterostructure to a thermal treatment before hydrogen is introduced into the first heterostructure.

18. The method of claim 17, wherein the thermal treatment comprises heating the first heterostructure at a temperature from about 100 degrees Celsius to about 1000 degrees Celsius for at least 1 second.

19. The method of claim 1, further comprising subjecting the first heterostructure to ion bombardment before hydrogen is introduced into the first heterostructure.

20. The method of claim 19, wherein the ion bombardment comprises ions selected from the group consisting of hydrogen, deuterium, helium, and silicon.

21. The method of claim 1, further comprising subjecting the first heterostructure to electron bombardment before hydrogen is introduced into the first heterostructure.

22. The method of claim 1, wherein the second substrate comprises at least one layer of material selected from the group consisting of oxidized silicon, glass, quartz and sapphire.

23. The method of claim 1, wherein splitting the second heterostructure at the layer of doped semiconductor comprises subjecting the second heterostructure to an externally applied force.

24. A method for forming a semiconductor structure, the method comprising:
forming a first heterostructure by depositing a doped semiconductor layer on a first substrate and thereafter depositing a semiconductor layer on the doped layer;
introducing hydrogen atoms into the doped layer;
bonding the first heterostructure to a second substrate to form a second heterostructure; and
splitting said second heterostructure at the doped layer.
